(19) United States
(12) Patent Application Publication
(10) Pub. No.: US 2025/0116707 A1
(43) Pub. Date: Apr. 10, 2025

(54) Faulty Battery Detection Apparatus and Method

(71) Applicant: LG Energy Solution, Ltd., Seoul (KR)

(72) Inventor: Eungyong Kim, Daejeon (KR)

(73) Assignee: LG Energy Solution, Ltd., Seoul (KR)

(21) Appl. No.: 18/836,417

(22) PCT Filed: Jul. 12, 2023
(86) PCT No.: PCT/KR2023/009914

§ 371 Date: Aug. 7, 2024

(30) Foreign Application Priority Data
Aug. 31, 2022 (KR) 10-2022-0109748

(51) Int. Cl. G01R 31/367; G01R 31/3842

(52) U.S. Cl. CPC G01R 31/367; G01R 31/3842

(57) ABSTRACT

An apparatus for detecting at least one abnormal battery among a plurality of batteries. The apparatus may include at least one processor and a memory configured to store at least one instruction executed by the at least one processor. At least one instruction may include an instruction to collect respective state data for each battery of the plurality of batteries; an instruction to calculate a respective correlation coefficient for each battery of the plurality of batteries by performing a correlation analysis on a respective battery states based on the collected respective state data; and an instruction to detect the at least one abnormal battery among the plurality of batteries based on the calculated respective correlation coefficient.

### CROSS-REFERENCE TO RELATED APPLICATION

The present application is a national phase entry under 35 U.S.C. § 371 of International Application No. PCT/KR2023/009914 filed Jul. 12, 2023, which claims priority from Korean Patent Application No. 10-2022-0109748 filed in the Korean Intellectual Property Office on Aug. 31, 2022, the entire contents of which are incorporated herein by reference.

### TECHNICAL FIELD

The present invention relates to an apparatus and method for detecting an abnormal battery, and more particularly, to an apparatus and method for detecting an abnormal battery among a plurality of batteries using correlation analysis.

### BACKGROUND

A secondary battery is a battery that can be recharged and reused even after being discharged. The secondary battery can be used as an energy source for small devices such as mobile phones, tablet PCs and vacuum cleaners, and also used as an energy source for medium and large devices such as automobiles and an energy storage system (ESS) for smart grids.

The secondary battery is applied to a system in a form of an assembly such as a battery module in which a plurality of battery cells are connected in series and parallel or a battery pack in which battery modules are connected in series and parallel according to system requirements. In a case of medium or large-sized devices such as electric vehicles, a high-capacity battery system in which a plurality of battery packs are connected in parallel may be applied in order to satisfy a required capacity of the device.

Since battery cells included in a battery assembly operate under the same conditions, they undergo the same or very similar degradation process. Thus, abnormal battery cells can be detected by collecting state values (e.g., voltage values) for battery cells in the battery assembly and comparing the state values of the battery cells.

In the case of an abnormal battery detection method using such a deviation in the state values, misdiagnosis may occur due to a deviation in the state values caused by factors other than battery failure. For example, voltage deviation between battery cells may occur due to open circuit voltage (OCV), internal resistance (IR), and measurement errors of voltage sensors, and in this case, a corresponding battery may be detected as an abnormal battery even though no failure occurs in the corresponding battery.

As a technology that can solve these problems of the prior art, an appropriate solution to more accurately detect abnormal batteries is needed.

### SUMMARY

### Technical Problem

To obviate one or more problems of the related art, embodiments of the present disclosure provide an apparatus for detecting an abnormal battery with improved detection accuracy.

To obviate one or more problems of the related art, embodiments of the present disclosure also provide a method for detecting an abnormal battery by the apparatus for detecting an abnormal battery.

### Technical Solution

In order to achieve the objective of the present disclosure, an apparatus for detecting at least one abnormal battery may detect at least one abnormal battery among a plurality of batteries and may include at least one processor and a memory configured to store at least one instruction executed by the at least one processor.

Here, the at least one instruction may include an instruction to collect respective state data for each battery of the plurality of batteries; an instruction to calculate a respective correlation coefficient for each battery of the plurality of batteries by performing a correlation analysis on a respective battery state based on the collected respective state data; and an instruction to detect the at least one abnormal battery among the plurality of batteries based on the calculated respective correlation coefficient.

The instruction to calculate the respective correlation coefficient may include an instruction to calculate the respective correlation coefficient for each battery of the plurality of batteries using a correlation analysis model which is defined based on a standard deviation and a covariance of battery state values.

Here, the instruction to calculate the respective correlation coefficient may include an instruction to calculate the respective correlation coefficient when an influence of sensing noise of a state measurement sensor is removed using the correlation analysis model on which a predefined noise constant is reflected.

The noise constant may be defined based on a measurement error value of the state measurement sensor.

The instruction to calculate the respective correlation coefficient may include an instruction to calculate the respective correlation coefficient using either one of a first correlation analysis model which is defined based on a standard deviation and a covariance of battery state values and a second correlation analysis model in which a noise constant is applied to the first correlation analysis model so as to remove an influence by sensing noise of a state measurement sensor.

The instruction to calculate the respective correlation coefficient may include an instruction to identify an operation mode of the plurality of batteries; and an instruction to, in response to the operation mode being a charge/discharge mode, calculate the respective correlation coefficient using the first correlation analysis model, and in response to the operation mode being an idle mode, calculate the respective correlation coefficient using the second correlation analysis model.

The instruction to calculate the respective correlation coefficient may include an instruction to calculate a covariance of the battery state values and a covariance of noise component values; and an instruction to calculate the respective correlation coefficient using the first correlation analysis model when the covariance of the battery state values exceeds the covariance of the noise component values, and to calculate the respective correlation coefficient using the second correlation analysis model when the covariance of the battery state values is less than or equal to the covariance of the noise component values.

The instruction to detect the at least one abnormal battery among the plurality of batteries may include an instruction to determine one battery of the plurality of batteries having the respective correlation coefficient below a predefined threshold as an abnormal battery.

The instruction to collect the respective state data may include an instruction to collect one or more among a respective voltage value of each battery and the plurality of batteries and a respective current value of each battery of the plurality of batteries per unit time.

According to another embodiment of the present disclosure, a method of detecting at least one abnormal battery among a plurality of batteries is disclosed. The method may include collecting respective state data for each battery of the plurality of batteries; calculating a respective correlation coefficient for each battery of the plurality of batteries by performing a correlation analysis on a respective battery state based on the collected respective state data; and detecting the at least one abnormal battery among the plurality of batteries based on the calculated respective correlation coefficient.

Calculating the respective correlation coefficient for each of the batteries may include calculating the respective correlation coefficient for each battery of the plurality of batteries using a correlation analysis model which is defined based on a standard deviation and a covariance of battery state values.

The calculating the respective correlation coefficient for each of the batteries may include calculating the respective correlation coefficient when an influence of sensing noise of a state measurement sensor is removed using the correlation analysis model on which a predefined noise constant is reflected.

The noise constant may be defined based on a measurement error value of the state measurement sensor.

Calculating the respective correlation coefficient for each of the batteries may include calculating the respective correlation coefficient using either one of a first correlation analysis model which is defined based on a standard deviation and a covariance of battery state values and a second correlation analysis model in which a noise constant is applied to the first correlation analysis model so as to remove an influence by sensing noise of a state measurement sensor.

Calculating the respective correlation coefficient for each of the batteries may include identifying an operation mode of the plurality of batteries; and in response to the operation mode being a charge/discharge mode, calculating the respective correlation coefficient using the first correlation analysis model, and in response to the operation mode being an idle mode, calculating the respective correlation coefficient using the second correlation analysis model.

Calculating the respective correlation coefficient for each of the batteries may include calculating a covariance of the battery state values and a covariance of noise component values; and calculating the respective correlation coefficient using the first correlation analysis model when the covariance of the battery state values exceeds the covariance of the noise component values; and calculating the respective correlation coefficient using the second correlation analysis model when the covariance of the battery state values is less than or equal to the covariance of the noise component values.

Detecting the at least one abnormal battery among the plurality of batteries may include determining one battery of the plurality of batteries having the respective correlation coefficient below a predefined threshold as an abnormal battery.

Collecting the respective state data may include collecting one or more among a respective voltage value of each battery of the plurality of batteries and a respective current value of each battery of the plurality of batteries per unit time.

### Advantageous Effects

According to the embodiment of the present invention as described above, an abnormal battery can be detected more accurately by detecting an abnormal battery based on a correlation coefficient derived using a correlation analysis model.

### BRIEF DESCRIPTION OF THE DRAWINGS

FIG. 1 is an operation flowchart of a general method for detecting an abnormal battery.

FIG. 2 is an example of misdiagnosis by the general method for detecting an abnormal battery.

FIG. 3 is a block diagram of an abnormal battery detection system according to embodiments of the present invention.

FIG. 4 is an operation flowchart of a method for detecting an abnormal battery according to embodiments of the present invention.

FIG. 5 is an operation flowchart of a method for deriving a correlation coefficient according to embodiments of the present invention.

FIG. 6 is an operation flowchart of a method for deriving a correlation coefficient according to another embodiment of the present invention.

FIGS. 7 to 10 show the results of detecting an abnormal battery using a correlation analysis model according to embodiments of the present invention.

FIG. 11 is a block diagram of an abnormal battery detection apparatus according to embodiments of the present invention.

10: battery
100: Battery assembly
200: Abnormal battery detection apparatus

### DETAILED DESCRIPTION OF THE DISCLOSURE

The present invention may be modified in various forms and have various embodiments, and specific embodiments thereof are shown by way of example in the drawings and will be described in detail below. It should be understood, however, that there is no intent to limit the present invention to the specific embodiments, but on the contrary, the present invention is to cover all modifications, equivalents, and alternatives falling within the spirit and technical scope of the present invention. Like reference numerals refer to like elements throughout the description of the figures.

It will be understood that, although the terms such as first, second, A, B, and the like may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes combinations of a plurality of associated listed items or any of the plurality of associated listed items.

It will be understood that when an element is referred to as being “coupled” or “connected” to another element, it can be directly coupled or connected to the other element or an intervening element may be present. In contrast, when an element is referred to as being “directly coupled” or “directly connected” to another element, there is no intervening element present.

The terms used herein is for the purpose of describing specific embodiments only and are not intended to limit the present invention. As used herein, the singular forms “a”, “an” and “the” are intended to include the plural forms as well, unless the context clearly indicates otherwise. It will be further understood that the terms “comprises”, “comprising”, “includes”, “including” and/or “having”, when used herein, specify the presence of stated features, integers, steps, operations, constitutional elements, components and/or combinations thereof, but do not preclude the presence or addition of one or more other features, integers, steps, operations, constitutional elements, components, and/or combinations thereof.

Unless otherwise defined, all terms used herein, including technical and scientific terms, have the same meanings as commonly understood by one skilled in the art to which the present invention belongs. It will be further understood that terms, such as those defined in commonly used dictionaries, should be interpreted as having meanings that are consistent with their meanings in the context of the relevant art and will not be interpreted in an idealized or overly formal sense unless expressly so defined herein.

Some terms used herein are defined as follows.

A battery cell is a minimum unit that serves to store power and a battery module refers to an assembly in which a plurality of battery cells are electrically connected.

A battery pack or battery rack refers to a system of a minimum single structure which is assembled by electrically connecting module units, set by a battery manufacturer, and can be monitored and controlled by a battery management apparatus/system (BMS). A battery pack or battery rack may include several battery modules and a battery protection unit or any other protection device.

A battery bank refers to a group of large-scale battery rack systems configured by connecting several racks in parallel. A bank BMS for a battery bank may monitor and control several rack BMSs, each of which manages a battery rack.

A battery assembly may include a plurality of electrically connected battery cells, and refers to an assembly that functions as a power supply source by being applied to a specific system or device. Here, the battery assembly may mean a battery module, a battery pack, a battery rack, or a battery bank, but the scope of the present invention is not limited to these entities.

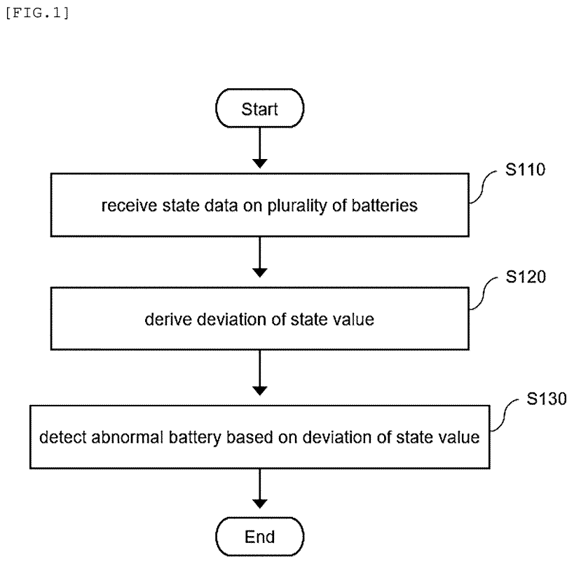

FIG. 1 is an operation flowchart of a general method for detecting an abnormal battery.

Referring to FIG. 1, according to a general method for detecting a faulty battery, an abnormal battery is detected among a plurality of batteries by using a deviation in state values of the batteries. More specifically, an abnormal battery detection device collects state data on batteries included in the battery assembly (S110). Thereafter, the abnormal battery detection device derives a deviation of the state value for each battery based on the collected state data (S120). Thereafter, the abnormal battery detection device detects a battery in which the deviation of the derived state value exceeds a predefined threshold as an abnormal battery (S130).

According to this general detecting method, misdiagnosis may occur due to deviations in state values caused by factors other than a battery fault.

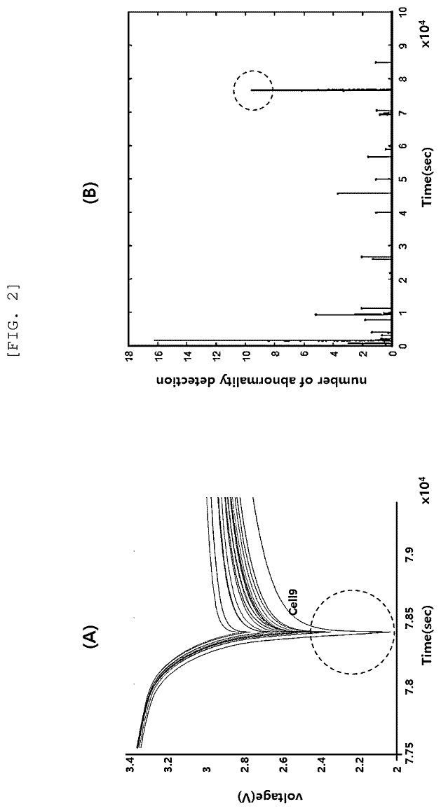

FIG. 2 is an example of misdiagnosis by the general method for detecting an abnormal battery.

FIG. 2(A) shows voltage values of batteries measured per unit time, and FIG. 2(B) shows abnormality diagnosis results based on voltage differences between battery cells.

Referring to FIG. 2(A), due to influences of an open circuit voltage (OCV) and an internal resistance (IR), the voltage of a specific battery (Cell 9) shows a difference from voltages of other batteries, and as shown in FIG. 2(B), a misdiagnosis, of which the specific battery is diagnosed as a faulty battery even though no fault has occurred in the specific battery, may occur due to the high voltage deviation at that point.

The present invention is presented to solve the problems caused by the general method stated above, and relates to an apparatus and method for detecting an abnormal battery, which can improve detection accuracy of an abnormal battery by preventing misdiagnosis due to factors other than failure.

Hereinafter, exemplary embodiments of the present invention will be described in detail with reference to the accompanying drawings.

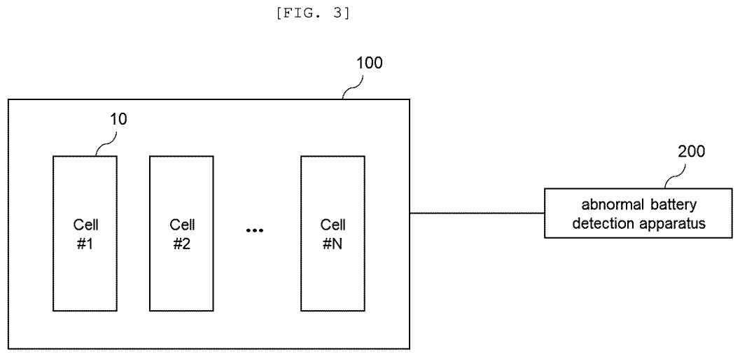

FIG. 3 is a block diagram of a system for abnormal battery detection according to embodiments of the present invention.

Referring to FIG. 3, the system for abnormal battery detection includes a battery assembly 100 including a plurality of batteries 10 and an abnormal battery detection apparatus 200.

A plurality of batteries 10 may be electrically connected to form a battery assembly 100.

The system for abnormal battery detection according to embodiments of the present invention may be included and implemented in an electric vehicle, but the scope of the present invention is not limited to this. In other words, the system for abnormal battery detection according to the present invention may be applied to a device which is equipped with a plurality of batteries and operate to detect an abnormal battery by performing an abnormal battery detection method described below.

In embodiments, the abnormal battery detection apparatus 200 may be implemented by being included in a battery management system (BMS) located inside the battery system.

The abnormal battery detection apparatus 200 may collect state data for each of a plurality of batteries. Here, the state data may correspond to data about one or more state values of voltage values and current values of the battery.

The abnormal battery detection apparatus 200 may receive state data from a state measurement sensor that measures state values for each battery. For example, the abnormal battery detection apparatus 200 may receive state data from a voltage measurement sensor that senses a voltage value of each of the batteries, or a current measurement sensor that senses a value of current flowing through each of the batteries.

The abnormal battery detection apparatus 200 may collect state data at each predefined unit time. For example, the abnormal battery detection apparatus 200 may be configured to receive state data for each battery every second.

The abnormal battery detection apparatus 200 may perform correlation analysis between battery states based on the collected state data and calculate a correlation coefficient for each of the batteries. Thereafter, the abnormal battery detection apparatus 200 may detect an abnormal battery among the plurality of batteries based on the calculated correlation coefficients. Here, the abnormal battery detection apparatus 200 may determine a battery with a correlation coefficient less than or equal to a predefined threshold as an abnormal battery.

The abnormal battery detection apparatus according to the present invention may detect an abnormal battery based on the state values of batteries operating under the same conditions. Hereinafter, a method for detecting an abnormal battery based on voltage values of batteries connected in parallel in a battery assembly will be described as an example, but the scope of the present invention is not limited thereto.

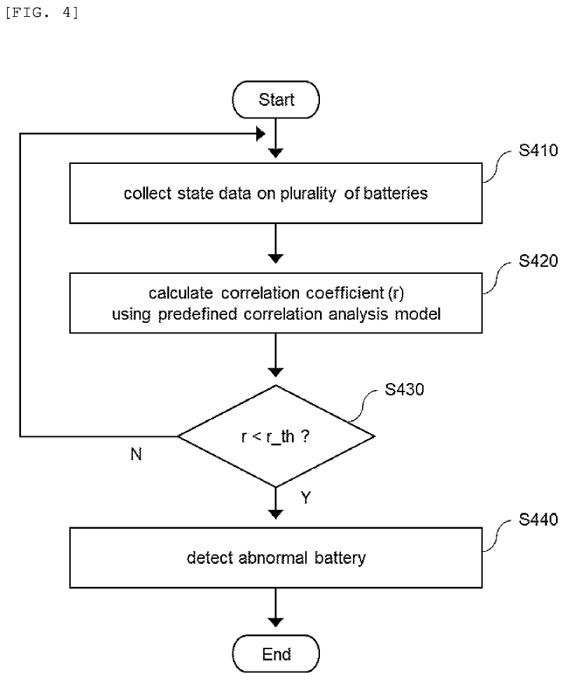

FIG. 4 is an operation flowchart of a method for detecting an abnormal battery according to embodiments of the present invention.

The abnormal battery detection apparatus 200 may collect state data for each of the plurality of batteries (S410). Here, the abnormal battery detection apparatus 200 may collect state data on one or more of a voltage value and a current value for each battery per unit time.

The abnormal battery detection apparatus 200 may perform correlation analysis between battery states based on the collected state data and calculate a correlation coefficient (r) for each of the batteries (S420).

The abnormal battery detection apparatus 200 may calculate a correlation coefficient for each battery using a predefined correlation analysis model. Here, the correlation analysis model may be defined so that when state data for a plurality of batteries is input, a correlation coefficient for each of the batteries is output.

The correlation analysis model (hereinafter, first correlation analysis model) according to a first embodiment of the present invention may be defined based on a standard deviation and a covariance of the battery state values. For example, the first correlation analysis model may be defined based on Equation 1 below.

$${r}_{X , Y} = \frac{{C0V}_{X , Y}}{{σ}_{X} {σ}_{Y}} = \frac{{\sum }_{i = 1}^{n} ( {x}_{i} - {μ}_{x} ) ( {y}_{i} - {μ}_{y} )}{\sqrt{{\sum }_{i = 1}^{n} {( {x}_{i} - {μ}_{x} )}^{2}} \sqrt{{\sum }_{i = 1}^{n} {( {y}_{i} - {μ}_{y} )}^{2}}} \qquad [ Equation l ]$$

Here, r_{X,Y} refers to a correlation coefficient between battery X and battery Y, COV_{X,Y} refers to a covariance of the state values of battery X and battery Y, ox means a standard deviation of the state value of battery X, and oy means a standard deviation of the state value of battery Y. In addition, x refers to the state value of battery X, μₓ is an average value of the state values of battery X for a predetermined period of time, y refers to the state value of battery Y, and μ_{y} means an average value of state values of battery Y for a predetermined period of time.

When deriving a correlation coefficient for a specific battery (e.g. Cell_1) based on Equation 1, the state data for the battery (Cell_1) is input as x, and the state data for other batteries are input as y to the correlation analysis model. Here, y may correspond to the average value or median value of the state values of other batteries. In embodiments, in order to accurately calculate the correlation coefficient, the abnormal battery detection apparatus 200 may correct the median value of the state values of other batteries according to a predefined process, and input the corrected median value as y into the correlation analysis model.

When a correlation coefficient is calculated using the first correlation analysis model according to embodiments of the present invention, and an abnormal battery is detected based on the calculated correlation coefficient, misdiagnosis due to the influence of open circuit voltage (OCV) or internal resistance (IR) can be prevented.

More specifically, in Equation 1 above, when the change in voltage values (αX+β) due to the influence of open circuit voltage (OCV) or internal resistance (IR) is reflected, the average value of the voltage values also changes accordingly and thus, the correlation coefficient may be calculated as the same value as the correlation coefficient according to equation 1, as shown in equation 2 below.

$${r}_{α X + β , Y} = {r}_{X , Y} \qquad [ Equation 2 ]$$

The abnormal battery detection apparatus 200 may calculate a correlation coefficient using the first correlation analysis model defined based on Equation 1, and detect an abnormal battery using the calculated correlation coefficient, and thus, misdiagnosis due to the influence of open circuit voltage (OCV) or internal resistance (IR) can be prevented.

In step S420, the abnormal battery detection apparatus 200 may calculate a correlation coefficient for each of the batteries using a correlation analysis model (hereinafter, second correlation analysis model) according to the second embodiment of the present invention. Here, the second correlation analysis model may be defined based on a standard deviation, a covariance, and a noise constant of the battery state values. For example, the correlation analysis model can be defined based on Equation 3 below.

$${r}_{X , Y} = \frac{{\sum }_{i = 1}^{n} ( {x}_{i} - {μ}_{x} ) ( {y}_{i} - {μ}_{y} ) + N}{\sqrt{{\sum }_{i = 1}^{n} {( {x}_{i} - {μ}_{x} )}^{2}} \sqrt{{\sum }_{i = 1}^{n} {( {y}_{i} - {μ}_{y} )}^{2}} + N} \qquad [ Equation 3 ]$$

Here, N refers to a noise constant and can be defined as Equation 4 below.

$$N = α * R M S ( Noise ) \qquad [ Equation 4 ]$$

Here, RMS (Noise) is a RMS (Root Mean Square) value of a measurement error value of a state measurement sensor, and a is a weighting coefficient.

Referring to Equation 3, the second correlation analysis model is a model in which a noise constant (N) is reflected in the first correlation analysis model to remove the influence of sensing noise of the state measurement sensor.

Generally, state values measured by a state measurement sensor include noise components. Equation 1 can be expressed as follows if these noise components are reflected in Equation 1.

$${r}_{X + N , Y + M} = \frac{{COV}_{X + N , Y + M}}{{σ}_{X + N} {σ}_{Y + M}} = \frac{( {\sum }_{i = 1}^{n} ( {x}_{i} - {μ}_{x} ) ( {y}_{i} - {μ}_{y} ) + {\sum }_{i = 1}^{n} ( {N}_{i} - {μ}_{N} ) ( {M}_{i} - {μ}_{M} ) )}{( \sqrt{{\sum }_{i = 1}^{n} {( {x}_{i} - {μ}_{x} )}^{2} + {\sum }_{i = 1}^{n} {( {N}_{i} - {μ}_{N} )}^{2}} \sqrt{{\sum }_{i = 1}^{n} {\sum }_{i = 1}^{n} {( {y}_{i} - {μ}_{y} )}^{2} + {\sum }_{i = 1}^{n} {( {M}_{i} - {μ}_{M} )}^{2}} )} = \frac{{C0V}_{X , Y} + {C0V}_{N , M}}{{σ}_{X + N} {σ}_{Y + M}} \qquad [ Equation 5 ]$$

Here, N means a noise component of x, and M means a noise component of y.

Depending on the relationship between the noise component and the original state value (the value from which the noise component is removed from the measured value), the following two cases can be assumed.

COV_{X,Y}>COV_{N,M} (case 1)

COV_{X,Y}≤COV_{N,M} (case 2)

Case 1 is a case where the amount of change in the original state values is greater than that of the noise components, and may correspond, for example, to a charging/discharging period of the battery. In Case 1, since the amount of change in the original state values is larger than that of the noise components, the influence of the sensing noise of the state measurement sensor is small, and thus, the detection accuracy is not significantly reduced even if the correlation coefficient is calculated using the first correlation analysis model.

Case 2 is a case where the amount of change in the original state values is less than or equal to that of the noise components, and may correspond, for example, to an idle period of the battery. In Case 2, since the change in noise components is larger than the change in the original state values, misdiagnosis may occur due to the influence of sensing noise when calculating the correlation coefficient using the first correlation analysis model.

In case 2, when COV_{X,Y}=COV_{N,M}, the noise components and the original state values have the same level of change, so equation 5 can be simplified as follows.

$${r}_{X + N , Y + M} = \frac{{COV}_{X , Y} + {COV}_{N , M}}{{σ}_{X + N} {σ}_{Y + M}} ≅ \frac{2 * {COV}_{N , M}}{{σ}_{2 * N} {σ}_{2 * M}} = \frac{2 * {Σ}_{i = 1}^{n} ( {N}_{i} - {μ}_{N} ) ( {M}_{i} - {μ}_{N} )}{\sqrt{2 * {{Σ}_{i = 1}^{n} ( {N}_{i} - {μ}_{N} )}^{2}} \sqrt{2 * {{Σ}_{i = 1}^{n} ( {M}_{i} - {μ}_{M} )}^{2}}} = \frac{{Σ}_{i = 1}^{n} ( {N}_{i} - {μ}_{N} ) ( {M}_{i} - {μ}_{M} )}{\sqrt{{{Σ}_{i = 1}^{n} ( {N}_{i} - {μ}_{N} )}^{2}} \sqrt{{{Σ}_{i = 1}^{n} ( {M}_{i} - {μ}_{M} )}^{2}}} = {r}_{N , M} \qquad [ Equation 6 ]$$

Here, if the noise component is white noise, the average value (μN, μM) of the noise components is 0, and if the state values of the batteries were measured by the same sensor, N=M, so equation 6 can be represented as follows.

$${r}_{N , M} = \frac{{\sum }_{i = 1}^{n} ( {N}_{i} - {μ}_{N} ) ( {M}_{i} - {μ}_{M} )}{\sqrt{{\sum }_{i = 1}^{n} {( {N}_{i} - {μ}_{N} )}^{2}} \sqrt{{\sum }_{i = 1}^{n} {( {M}_{i} - {μ}_{M} )}^{2}}} = \frac{{\sum }_{i = 1}^{n} ( {N}_{i} ) ( {M}_{i} )}{\sqrt{{\sum }_{i = 1}^{n} {( {N}_{i} )}^{2}} \sqrt{{\sum }_{i = 1}^{n} {( {M}_{i} )}^{2}}} = 1 \qquad [ Equation 7 ]$$

In other words, in case 2, since the same result can be obtained even if the correlation coefficient (r_{x+N,Y+M}) is calculated by adding an appropriate noise constant N to the numerator and the denominator of equation 1, respectively, the second correlation analysis model defined according to equation 3 can be used.

The noise constant N may be defined as RMS (Noise) multiplied by the weighting coefficient a, according to Equation 4. For example, the noise constant N may be defined as the RMS value of 5 mV, which is the measurement error value of the voltage sensor, multiplied by a weighting factor of 0.8.

The weighting coefficient a is a value for adjusting detection accuracy and may be defined as a specific value between 0.2 and 1.1, and preferably, a specific value between 0.8 and 1.0.

The abnormal battery detection apparatus 200 may calculate the correlation coefficient using a second correlation analysis model defined based on equation 3 for case 2 (e.g., idle mode), but the correlation coefficient may be calculated using a second correlation analysis model even for case 1 (e.g., charge/discharge mode), in order to achieve higher detection accuracy.

The abnormal battery detection apparatus 200 may compare the correlation coefficient (r) calculated for each battery in step S420 with a predefined threshold (r_th) (S430). The correlation coefficient (r) according to embodiments of the present invention may indicate a degree to which the state of a specific battery is correlated with states of other batteries, and may be calculated as a specific value between −1 and 1. A battery with a correlation coefficient (r) close to 1 may be considered to have high correlation with other batteries, and a battery with a correlation coefficient (r) close to 0 may be considered as having low correlation with other batteries.

The abnormal battery detection apparatus 200 may determine a battery having a correlation coefficient less than or equal to the threshold value (r_th) as an abnormal battery (S440). For example, when the threshold (r_th) is defined as 0.5, the abnormal battery detection apparatus 200 may determine a battery with a correlation coefficient of 0.5 or less among a plurality of batteries as an abnormal battery. Meanwhile, the threshold value (r_th) may be determined as an appropriate value as needed and may be defined as a specific value between 0.4 and 0.8.

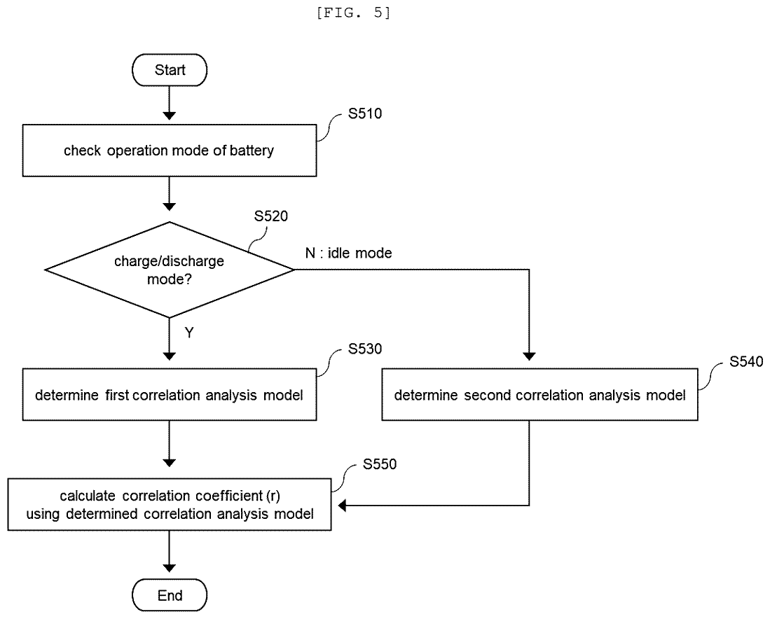

FIG. 5 is an operation flowchart of a method for deriving a correlation coefficient according to embodiments of the present invention.

The abnormal battery detection apparatus 200 may check the operation mode of the batteries (S510). Here, the operation mode may include charge/discharge mode and idle mode.

The abnormal battery detection apparatus 200 may determine an operation mode based on output current values or input current values for the batteries. For example, the operation mode may be determined as the idle mode if the output or input current value of the batteries is 0, and the operation mode may be determined as the charge/discharge mode if the output or input current value is not 0.

The abnormal battery detection apparatus 200 may also determine the operation mode based on a battery operation state signal received from an external device. For example, the abnormal battery detection apparatus 200 may receive a battery operation state signal from a battery charge/discharge control device and determine whether the battery is in a charge/discharge state or an idle state.

When the operation mode of the battery is the charge/discharge mode (Y in S520), the abnormal battery detection apparatus 200 may determine a first correlation analysis model defined based on equation 1 as a model for calculating the correlation coefficient (S530).

When the operation mode of the battery is the idle mode (N in S520), the abnormal battery detection apparatus 200 may determine a second correlation analysis model defined based on equation 3 as a model for calculating the correlation coefficient (S540).

The abnormal battery detection apparatus 200 may derive a correlation coefficient (r) for each of the batteries using the correlation analysis model determined according to the operation mode of the battery (S550).

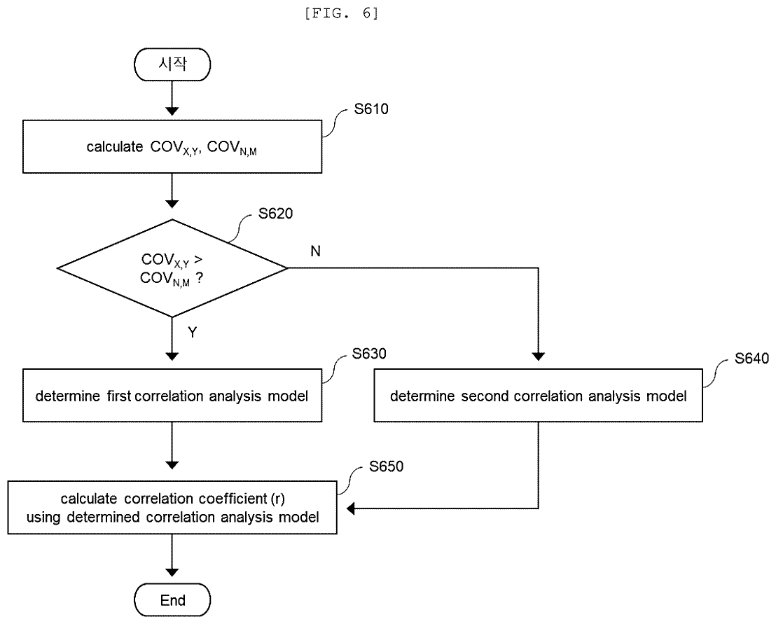

FIG. 6 is an operation flowchart of a method for deriving a correlation coefficient according to another embodiment of the present invention.

The abnormal battery detection apparatus 200 may calculate COV_{X,Y} and COV_{N,M} based on the state data of the batteries (S610).

Here, COV_{X,Y} and COV_{N,M} may be calculated based on the equations below.

$${COV}_{X , Y} = {\sum }_{i = 1}^{n} ( {x}_{i} - {μ}_{x} ) ( {y}_{i} - {μ}_{y} ) \qquad [ Equation 8 ]$$

$${COV}_{N , M} = {\sum }_{i = 1}^{n} ( {N}_{i} - {μ}_{N} ) ( {M}_{i} - {μ}_{M} )$$

The abnormal battery detection apparatus 200 may compare COV_{X,Y} and COV_{N,M} (S620).

When COVX,Y exceeds COVN,M (Y in S620), the abnormal battery detection apparatus 200 may determine the first correlation analysis model defined based on equation 1 as a model for calculating the correlation coefficient (S630).

When COV_{X,Y} is less than or equal to COV_{N,M} (N in S620), the abnormal battery detection apparatus 200 may determine the second correlation analysis model defined based on equation 3 as a model for calculating the correlation coefficient (S640).

The abnormal battery detection apparatus 200 may derive a correlation coefficient (r) for each of the batteries using the correlation analysis model determined according to the operation mode of the battery (S650).

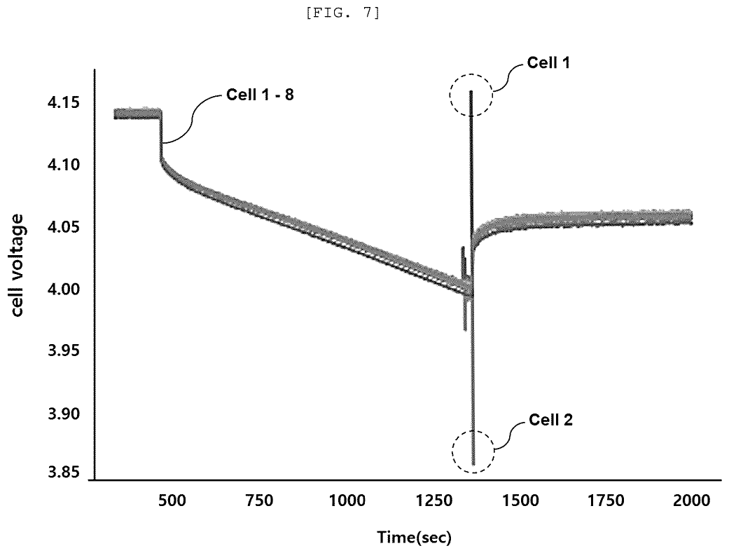

FIGS. 7 to 10 show the results of detecting an abnormal battery using a correlation analysis model according to embodiments of the present invention.

FIG. 7 shows voltage measurement values for each of eight batteries (Cells 1 to 8) connected in parallel. Referring to FIG. 7, it seems that an abnormal voltage phenomenon occurs in Cell 1 and Cell 2 approximately at 1375 sec.

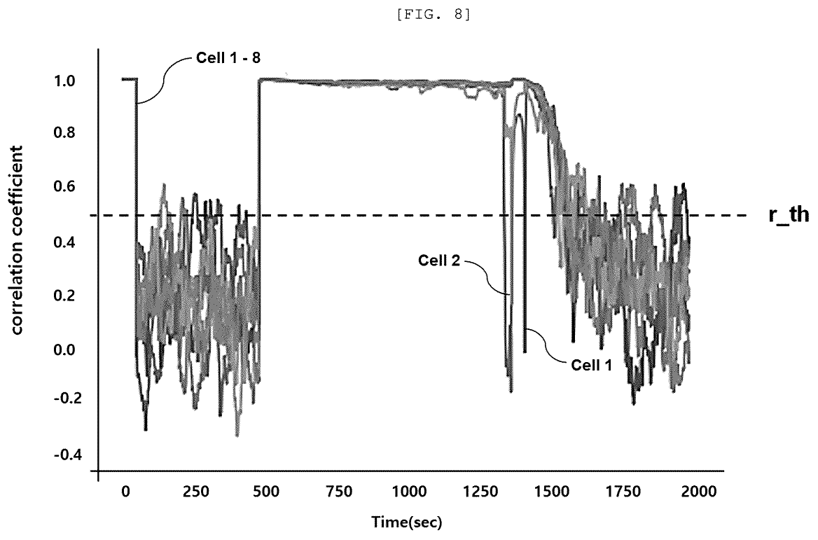

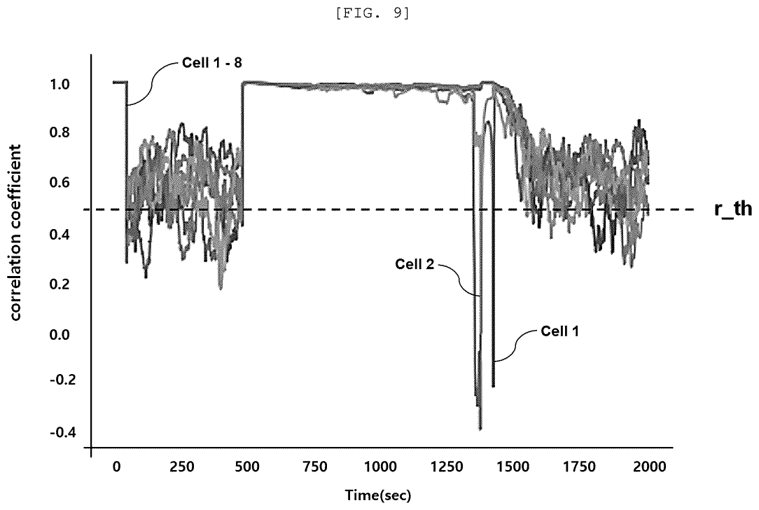

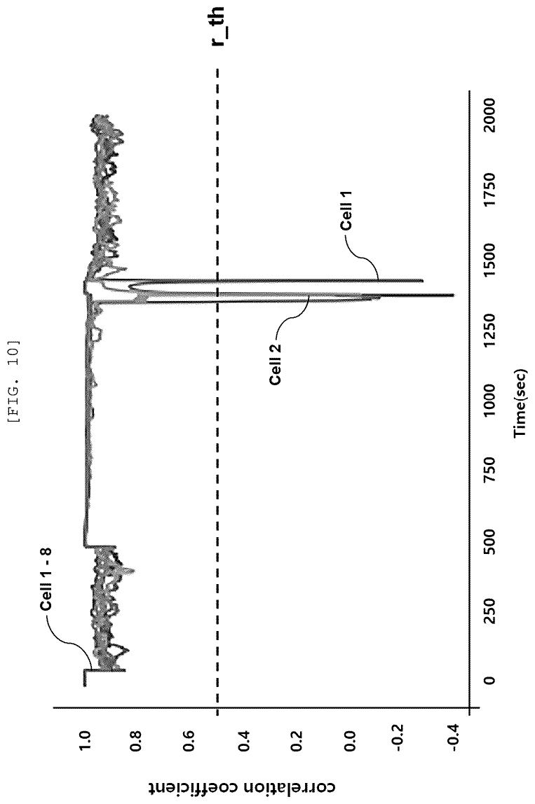

FIGS. 8 to 10 show correlation coefficients for each battery cell calculated by applying a correlation analysis model according to embodiments of the present invention. FIG. 8 is a graph of the results of applying the first correlation analysis model, FIG. 9 is a graph of the results of applying the second correlation analysis model where the weighting coefficient a is defined as 0.1 and the RMS (Noise) is defined as a value of 0.5 mV, and FIG. 10 is a graph of the results of applying the second correlation analysis model where the weighting coefficient α is 1.0 and the RMS (Noise) is defined as a value of 0.5 mV. The threshold (r_th) for detecting an abnormal battery is set to 0.5.

Referring to FIG. 8, when using the first correlation analysis model, a battery with a correlation coefficient of equal to or less than the threshold value (0.5) is detected in a section other than the time point where the abnormal voltage phenomenon occurred, and a false detection was made that cells 3 to 8 are classified as abnormal batteries.

Referring to FIG. 9, when using the second correlation analysis model in which the weighting coefficient a is defined as 0.1, a battery with a correlation coefficient of equal to or less than the threshold value (0.5) is detected in a section other than the time point where the abnormal voltage phenomenon occurred, and a false detection was made that cells 3 to 8 are classified as abnormal batteries, as in the case of FIG. 8.

Referring to FIG. 10, when using the second correlation analysis model in which the weighting coefficient a is defined as 1.0, cell 1 and cell 2 are detected as batteries with a correlation coefficient equal to or less than the threshold value (0.5).

Referring to FIGS. 8 to 10, it can be understood that when the second correlation analysis model with a weighting coefficient within optimal range (0.2 or more and 1.1 or less) is applied, abnormal battery detection can be performed with high accuracy.

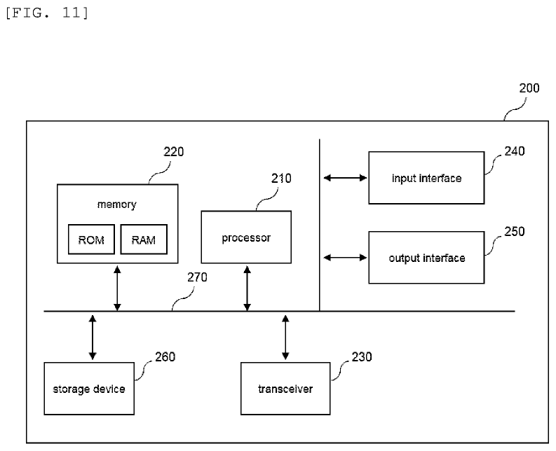

FIG. 11 is a block diagram of an abnormal battery detection apparatus according to embodiments of the present invention.

The abnormal battery detection apparatus 200 according to embodiments of the present invention includes at least one processor 210 and a memory 220 that stores at least one command executed through the processor, and is connected to a network to perform communication. It may include a transmitting and receiving device 230.

Here, the at least one instruction may include an instruction to collect state data for each of the plurality of batteries; an instruction to calculate a correlation coefficient for each of the batteries by performing correlation analysis between battery states based on the collected state data; and an instruction to detect the at least one abnormal battery among a plurality of batteries based on the calculated correlation coefficient.

The instruction to calculate the correlation coefficient may include an instruction to calculate the correlation coefficient for each of the batteries using a correlation analysis model which is defined based on a standard deviation and a covariance of battery state values.

Here, the instruction to calculate the correlation coefficient may include an instruction to calculate a correlation coefficient in which influence of sensing noise of a state measurement sensor is removed using a correlation analysis model on which a predefined noise constant is reflected.

The noise constant may be defined based on a measurement error value of the state measurement sensor.

The instruction to calculate the correlation coefficient may include an instruction to calculate the correlation coefficient using either one of a first correlation analysis model which is defined based on standard deviation and covariance of battery state values and a second correlation analysis model in which a noise constant is reflected to the first correlation analysis model so as to remove the influence by sensing noise of a state measurement sensor.

The instruction to calculate the correlation coefficient may include an instruction to identify the operation mode of the batteries; and an instruction to, upon the operation mode being charge/discharge mode, calculate the correlation coefficient using the first correlation analysis model, and upon the operation mode being idle mode, calculate the correlation coefficient using the second correlation analysis model.

The instruction to calculate the correlation coefficient may include an instruction to calculate a covariance of the battery state values and a covariance of the noise component values; and an instruction to calculate the correlation coefficient using the first correlation analysis model in the instance that the covariance of the battery state values exceeds the covariance of the noise component values, and to calculate the correlation coefficient using the second correlation analysis model in the instance that the covariance of the battery state values is less than or equal to the covariance of the noise component values.

The instruction to detect the at least one abnormal battery among a plurality of batteries may include an instruction to determine a battery having the correlation coefficient below a predefined threshold as an abnormal battery.

The instruction to collect state data may include an instruction to collect one or more of a voltage value and a current value for each of the batteries per unit time.

The abnormal battery detection apparatus 200 may further include an input interface 240, an output interface 250, a storage device 260, etc. Respective components included in the abnormal battery detection apparatus 200 are connected by a bus 270 and can communicate with one another.

Here, the processor 210 may mean a central processing unit (CPU), a graphics processing unit (GPU), or a dedicated processor on which methods according to embodiments of the present invention are performed. The memory (or storage device) may include at least one of a volatile storage medium and a non-volatile storage medium. For example, the memory may include at least one of read only memory (ROM) and random access memory (RAM).

The operations of the method according to the embodiments of the present invention may be implemented as a computer-readable program or code on a computer-readable recording medium. The computer-readable recording medium includes all types of recording devices in which data readable by a computer system is stored. In addition, the computer-readable recording medium may be distributed in a network-connected computer system to store and execute computer-readable programs or codes in a distributed manner.

Although some aspects of the invention have been described in the context of the apparatus, it may also represent a description according to a corresponding method, wherein a block or apparatus corresponds to a method step or feature of a method step. Similarly, aspects described in the context of a method may also represent a feature of a corresponding block or item or a corresponding apparatus. Some or all of the method steps may be performed by (or using) a hardware device, such as, for example, a microprocessor, a programmable computer, or an electronic circuit. In some embodiments, one or more of the most important method steps may be performed by such an apparatus.

In the forgoing, the present invention has been described with reference to the exemplary embodiment of the present invention, but those skilled in the art may appreciate that the present invention may be variously corrected and changed within the range without departing from the spirit and the area of the present invention described in the appending claims.

1. An apparatus for detecting at least one abnormal battery among a plurality of batteries, the apparatus comprising:
at least one processor; and
a memory configured to store at least one instruction executed by the at least one processor,
wherein the at least one instruction includes:
an instruction to collect respective state data for each battery of the plurality of batteries;
an instruction to calculate a respective correlation coefficient for each battery of the plurality of batteries by performing a correlation analysis on a respective battery states based on the collected respective state data; and
an instruction to detect the at least one abnormal battery among the plurality of batteries based on the calculated respective correlation coefficient.

2. The apparatus of claim 1, wherein the instruction to calculate the respective correlation coefficient includes:
An instruction to calculate the respective correlation coefficient for each battery of the plurality of batteries using a correlation analysis model which is defined based on a standard deviation and a covariance of battery state values.

3. The apparatus of claim 2, wherein the instruction to calculate the respective correlation coefficient includes:
an instruction to calculate the respective correlation coefficient when an influence of sensing noise of a state measurement sensor is removed using the correlation analysis model on which a predefined noise constant is reflected.

4. The apparatus of claim 3, wherein the noise constant is defined based on a measurement error value of the state measurement sensor.

5. The apparatus of claim 1, wherein the instruction to calculate the respective correlation coefficient includes:
an instruction to calculate the respective correlation coefficient using either one of a first correlation analysis model which is defined based on a standard deviation and a covariance of battery state values and a second correlation analysis model in which a noise constant is applied to the first correlation analysis model so as to remove an influence by sensing noise of a state measurement sensor.

6. The apparatus of claim 5, wherein the instruction to calculate the respective correlation coefficient includes:
an instruction to identify an operation mode of the plurality of batteries; and
an instruction to, in response to the operation mode being a charge/discharge mode, calculate the respective correlation coefficient using the first correlation analysis model, and
in response to the operation mode being an idle mode, calculate the respective correlation coefficient using the second correlation analysis model.

7. The apparatus of claim 5, wherein the instruction to calculate the respective correlation coefficient includes:
an instruction to calculate a covariance of the battery state values and a covariance of noise component values; and
an instruction to calculate the respective correlation coefficient using the first correlation analysis model when the covariance of the battery state values exceeds the covariance of the noise component values, and to calculate the respective correlation coefficient using the second correlation analysis model when the covariance of the battery state values is less than or equal to the covariance of the noise component values.

8. The apparatus of claim 1, wherein the instruction to detect the at least one abnormal battery among the plurality of batteries includes:
an instruction to determine one battery of the plurality of batteries having the respective correlation coefficient below a predefined threshold as an abnormal battery.

9. The apparatus of claim 1, wherein the instruction to collect the respective state data includes:
an instruction to collect one or more among a respective voltage value of each battery of the plurality of batteries and a respective current value of each battery of the plurality of batteries per unit time.

10. A method of detecting at least one abnormal battery among a plurality of batteries, the method comprising:
collecting respective state data for each battery of the plurality of batteries;
calculating a respective correlation coefficient for each battery of the plurality of batteries by performing a correlation analysis on a respective battery states based on the collected respective state data; and
detecting the at least one abnormal battery among the plurality of batteries based on the calculated respective correlation coefficient.

11. The method of claim 10, wherein calculating the respective correlation coefficient for each of the batteries includes:
calculating the respective correlation coefficient for each battery of the plurality of batteries using a correlation analysis model which is defined based on a standard deviation and a covariance of battery state values.

12. The method of claim 11, wherein the calculating the respective correlation coefficient for each of the batteries includes:
calculating the respective correlation coefficient when an influence of sensing noise of a state measurement sensor is removed using the correlation analysis model on which a predefined noise constant is reflected.

13. The method of claim 12, wherein the noise constant is defined based on a measurement error value of the state measurement sensor.

14. The method of claim 10, wherein the calculating the respective correlation coefficient for each of the batteries includes:
calculating the respective correlation coefficient using either one of a first correlation analysis model which is defined based on a standard deviation and a covariance of battery state values and a second correlation analysis model in which a noise constant is applied to the first correlation analysis model so as to remove an influence by sensing noise of a state measurement sensor.

15. The method of claim 14, wherein the calculating the respective correlation coefficient for each of the batteries includes:
identifying an operation mode of the plurality of batteries; and
in response to the operation mode being a charge/discharge mode, calculating the respective correlation coefficient using the first correlation analysis model, and
in response to the operation mode being an idle mode, calculating the respective correlation coefficient using the second correlation analysis model.

16. The method of claim 14, wherein the calculating the respective correlation coefficient for each of the batteries includes:
calculating a covariance of the battery state values and a covariance of noise component values;
calculating the respective correlation coefficient using the first correlation analysis model when the covariance of the battery state values exceeds the covariance of the noise component values; and
calculating the respective correlation coefficient using the second correlation analysis model when the covariance of the battery state values is less than or equal to the covariance of the noise component values.

17. The method of claim 10, wherein the detecting the at least one abnormal battery among the plurality of batteries includes:
determining one battery of the plurality of batteries having the respective correlation coefficient below a predefined threshold as an abnormal battery.

18. The method of claim 10, wherein the collecting the respective state data includes:
collecting one or more among a respective voltage value of each battery of the plurality of batteries and a respective current value off each battery of the plurality of batteries per unit time.
